(19) United States
(12) Patent Application Publication
(10) Pub. No.: US 2021/0225898 A1
(43) Pub. Date: Jul. 22, 2021

(54) MANUFACTURING METHOD OF TFT ARRAY SUBSTRATE AND TFT ARRAY SUBSTRATE

(71) Applicant: SHENZHEN CHINA STAR OPTOELECTRONICS TECHNOLOGY CO., LTD., Guangdong (CN)

(72) Inventor: Qianyi Zhang, Guangdong (CN)

(21) Appl. No.: 16/094,351

(22) PCT Filed: Sep. 7, 2018
(86) PCT No.: PCT/CN2018/104554

§ 371 Date: Oct. 17, 2018

(30) Foreign Application Priority Data
Jun. 4, 2018 (CN) 201810561085.9

(51) Int. Cl. H01L 27/12

(52) U.S. Cl. CPC H01L 27/1259; H01L 27/1225

(57) ABSTRACT

A manufacturing method of a thin film transistor (TFT) array substrate and a TFT array substrate include forming a gate electrode, a gate insulating layer, and an active layer on a surface of a substrate in order. The active layer includes a channel, a source doped region, and a drain doped region. A protective layer is formed on a surface of the channel, and the source doped region and the drain doped region are made conductive. A source electrode and a drain electrode both are formed on the surface of the substrate, the protective layer is stripped, and a passivation layer is formed on the surface of the substrate.

### CROSS REFERENCE TO RELATED APPLICATIONS

This application is a U.S. National Phase application submitted under 35 U.S.C. § 371 of Patent Cooperation Treaty Application serial No. PCT/CN2018/104554, filed Sep. 7, 2018, which claims the priority of China Patent Application serial No. 201810561085.9, filed Jun. 4, 2018, the disclosures of which are incorporated herein by reference in their entirety.

### BACKGROUND OF INVENTION

### 1. Field of Invention

The present invention relates to flat panel displaying, and particularly to a manufacturing method of a thin film transistor (TFT) array substrate and a TFT array substrate.

### 2. Related Art

Currently, due to advantages of micro power consumption, low operational voltage, zero X-ray radiation, high definition, and compact size, thin film transistor-liquid crystal display (TFT-LCD) panels are widely used in mobile electronic products, such as mobile phones or tablets. TFTs are switches for controlling light emittance and are a key factor in realizing large size LCD devices, relating directly to high performance flat panel displays development trends. Nowadays, because of a selection ratio problem in manufacturing processes, bottom gate type indium gallium zinc oxide (IGZO) of a TFT structure is damaged by etching, which results in surface deficiency of IGZO and adversely affects device leakage current, threshold voltage, and stability. In the event that source/drain electrodes are of copper, poor adhesive force between the copper and substrates, SiO, or SiNx, and copper spreading to channels are problems that result in the need of an additional barrier layer material, thereby increasing etching cost and giving rise to residual risk.

Accordingly, in current TFT array substrates and manufacturing method thereof, due to poor adhesive force between source/drain electrodes and substrates or gate insulating layers in manufacturing processes of TFT array substrates, the source/drain electrodes are thus spread to active layer channels, resulting in the need of an additional barrier layer material, thereby increasing etching cost and giving rise to residual risk.

### SUMMARY OF INVENTION

An object of the present invention is to provide a manufacturing method of a thin film transistor (TFT) array substrate and a TFT substrate to prevent source/drain electrodes from leaving residues in manufacturing processes of current TFT array substrates, and to overcome technical problems that additional barrier layer material is needed because of the residues of the source/drain electrodes in channels, thereby to increase in etching cost and to give rise to residual risk.

To achieve the above mentioned object, the manufacturing method of a TFT array substrate of the present invention comprises:

S10, providing a substrate and forming a gate electrode on a surface of the substrate, and forming a gate insulating layer on the surface of the substrate;

S20, forming an active layer on a surface of the gate insulating layer, the active layer comprising a channel, a source doped region located at an end of the channel, and a drain doped region located at another end of the channel;

S30, forming a protective layer on a surface of the channel, and making the source doped region and the drain doped region conductive;

S40, forming a metal layer on the substrate, and etching the metal layer to form a source electrode and a drain electrode; and

S50, stripping the protective layer, and forming a passivation layer on the surface of the substrate.

In one aspect of the present invention, the active layer is made of metal oxide comprising indium gallium zinc oxide or indium zinc oxide.

In another aspect of the present invention, the protective layer is a photoresist.

In one aspect of the present invention, the step S30 further comprises:

S301, forming patterns on the substrate after developing the substrate through a halftone mask; and

S302, performing an ashing process on the protective layer.

In one aspect of the present invention, a gas utilized in the ashing process is one or a combination of oxygen and trifluoromethane, and an ashing time is between 20 to 100 seconds.

In one aspect of the present invention, a gas utilized in making the source doped region and the drain doped region conductive is a noble gas, and a time of making the source doped region and the drain doped region conductive is between 30 to 60 seconds.

In one aspect of the present invention, the source electrode and the drain electrode are made of copper.

In one aspect of the present invention, the gate insulating layer and the passivation layer are composite layer structures made of a combination of at least two materials of silicon oxide, silicon nitride, or nitrogen-silicon compounds.

In one aspect of the present invention, the active layer has a thickness of 40 nanometers, both the source electrode and the drain electrode have a thickness of 500 nanometers, and the passivation layer has a thickness of 100 to 400 nanometers.

The present invention further provides a TFT substrate, comprising:

a substrate;

a gate electrode formed on a surface of the substrate;

a gate insulating layer formed on the surface of the substrate;

an active layer formed on a surface of the gate insulting layer, the active layer comprising a channel, a source doped region located at an end of the channel, and a drain doped region located at another end of the channel;

a source electrode and a drain electrode both formed on the surface of the substrate; and

a passivation layer formed on the surface of the substrate.

The present invention has following advantages: the present invention provides a manufacturing method of a TFT array substrate and a TFT array substrate, making the source doped region and the drain doped region conductive to avoid the need of additional barrier layer material, thereby to lessen difficulty in etching, to prevent loss of active layer channels from etching, and finally to lower manufacturing cost of the TFT array substrate.

### BRIEF DESCRIPTION OF DRAWINGS

FIG. 1 is a flowchart of a manufacturing method of a thin film transistor (TFT) array substrate of the present invention.

FIGS. 1A-1E are schematic views of the manufacturing method of the TFT array substrate of FIG. 1.

FIG. 2 is a schematic structural view of a TFT array substrate of the present invention.

### DESCRIPTION OF PREFERRED EMBODIMENTS

The following embodiments are referring to the accompanying drawings for exemplifying specific implementable embodiments of the present disclosure. Furthermore, directional terms described by the present disclosure, such as upper, lower, front, back, left, right, inner, outer, side, etc., are only directions by referring to the accompanying drawings, and thus the used directional terms are used to describe and understand the present disclosure, but the present disclosure is not limited thereto. In the drawings, elements with similar structures are labeled with like reference numerals.

The present invention is directed to solve a problem in current thin film transistor (TFT) array substrates that due to poor adhesive force between source/drain electrodes and substrates or gate insulating layers in manufacturing processes of TFT array substrates, the source/drain electrodes are thus spread to active layer channels, resulting in the need of additional barrier layer material, thereby to increase in etching cost and to give rise to residual risk.

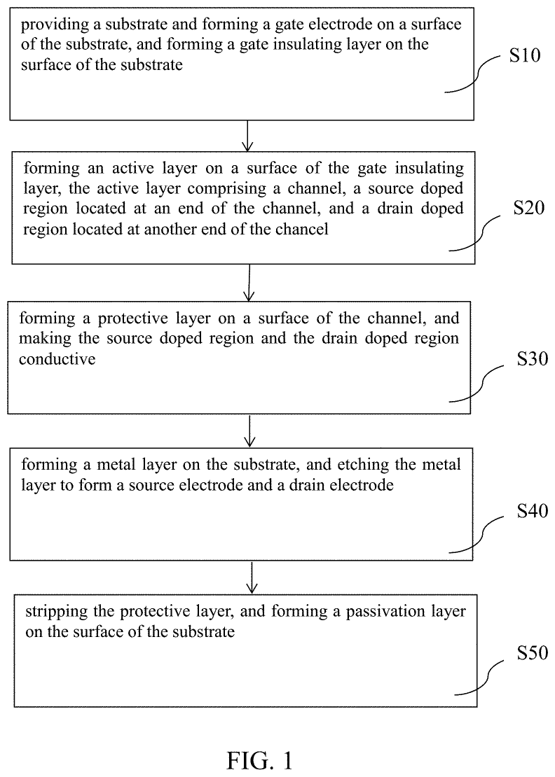

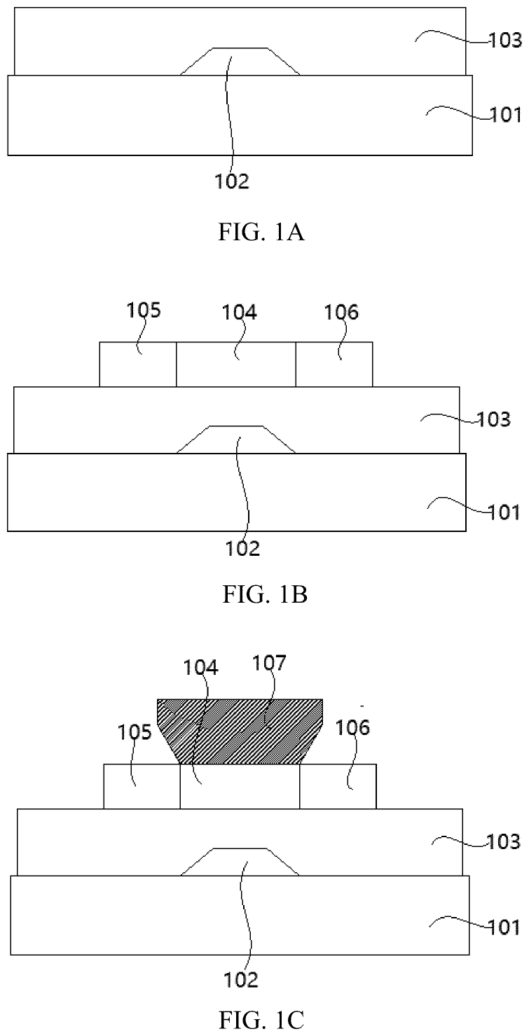

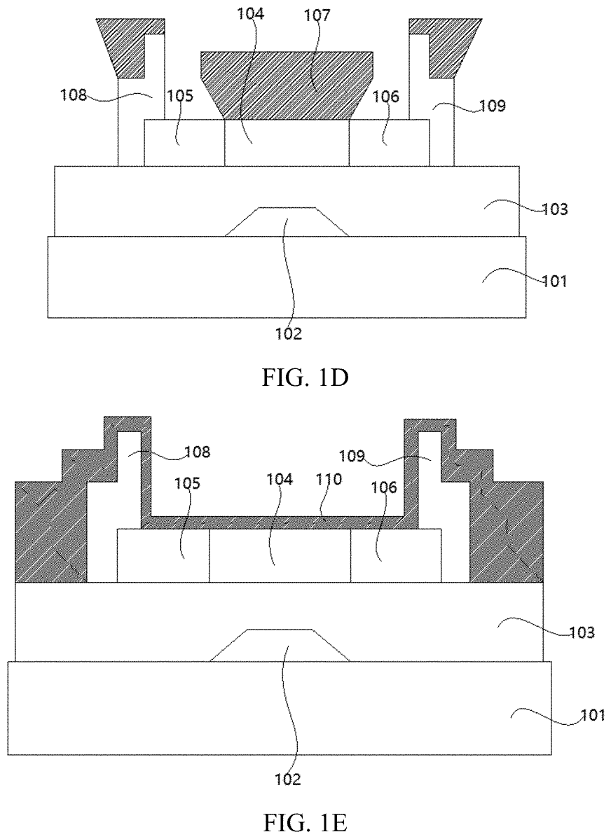

FIG. 1 shows a flowchart of a manufacturing method of a TFT array substrate. The manufacturing method of the present invention comprises following steps:

S10: providing a substrate 101 and forming a gate electrode 102 on a surface of the substrate, and then forming a gate insulating layer 103 on the surface of the substrate.

Specifically, S10 further comprises: first, performing etching on the surface of the substrate 101 by physical vapor deposition to form gate electrode patterns, so that the gate electrode 102 is formed; then, performing physical vapor deposition on the surface of the substrate 101 with the gate electrode 102 to form the gate insulating layer 103, as shown in FIG. 1A.

The substrate 101 is exemplified by a glass substrate. The gate electrode 102 is made of composite layer material of Cu/Ti, wherein a Cu layer of the gate electrode 102 has a thickness of 300 nm, and a Ti layer of the gate electrode 102 has a thickness of 30 nm. The gate insulating layer 103 is a composite layer structure made of a combination of at least two materials of silicon oxide, silicon nitride, or nitrogen-silicon compounds, and the gate insulting layer has a thickness of 300 nm.

S20, forming an active layer on a surface of the gate insulating layer 103. The active layer comprises a channel 104, a source doped region 105 located at an end of the channel 104, and a drain doped region 106 located at another end of the channel 104.

Specifically, S20 further comprises: performing physical vapor deposition on the surface of the gate insulating later 103 to form the active layer. The active layer comprises the channel 104, the source doped region 105 located at the end of the channel, and the drain doped region 106 located at the other end of the channel, as shown in FIG. 1B.

The active layer is made of metal oxide comprising indium gallium zinc oxide or indium zinc oxide, and the active layer has a thickness of 40 nm. The source doped region 105 has a size same as that of the drain doped region 106 located at the other end of the channel.

S30, forming a protective layer 107 on a surface of the channel 104, and making the source doped region 105 and the drain doped region 106 conductive.

Specifically, S30 further comprises: first, coating the substrate 101 with the protective layer, and forming patterns on the substrate through a halftone mask after developing the substrate; performing an ashing process on the protective layer, reducing the thickness of the protective layer on the surface of the substrate 101 to allow the channel 104 to be covered completely by a photoresist, and making the source doped region 105 and the drain doped region 106 conductive through plasma, as shown in FIG. 1C.

The protective layer 104 is a photoresist. The photoresist is exemplified by positive resistance material. A gas utilized in the ashing process is one or a combination of oxygen and trifluoromethane, and an ashing time is between 20 to 100 seconds. Preferably, a gas utilized in the ashing process is a mixture gas of trifluoromethane and oxygen, and the ashing time is 30 seconds. Preferably, a gas utilized in the ashing process is oxygen, and the ashing time is 40 seconds. A gas utilized in making the source doped region and the drain doped region conductive is a noble gas, and a time of making the source doped region and the drain doped region conductive is between 30 to 60 seconds.

S40, forming a metal layer on the substrate 101, and etching the metal layer to form a source electrode 108 and a drain electrode 109.

Specifically, S40 further comprises: first, performing physical vapor deposition on the surface of the substrate 101 to form the metal layer, and then etching the metal layer to form the source electrode 108 and the drain electrode 109 through a photoresist. At this phase, because the channel 104 is protected by the protective layer 107, the channel 104 is not affected by processes of etching the metal layer, and thereby to prevent the channel from being etched. The source doped region and the drain doped region made conductive function as barrier layer material and thus prevent the metal layer from spreading to the channel 104, as shown in 1D.

The metal layer is made of copper and has a thickness of 500 nanometers. Fluorocopper acid is allowed not to be used during the processes of etching.

S50, stripping the protective layer 107, and finally forming a passivation layer 110 on the surface of the substrate 101.

Specifically, S50 further comprises: utilizing stripping solution to strip the protective layer 107, and depositing the passivation layer on the substrate 101. At this phase, all of the channels of the TFT array substrate are being patterned, as shown in FIG. 1E.

The passivation layer 110 is a composite layer structure made of the combination of at least two materials of silicon oxide, silicon nitride, or nitrogen-silicon compounds. The passivation layer 110 has a thickness of 100-400 nanometers. A thermal evaporation gas utilized in processes of forming the passsivation layer is N₂ or O₂. A thermal evaporation process time is between 60-150 minutes, and a thermal evaporation process temperature is between 200-400° C. Preferably, the passivation layer 110 is a SiO/SiNx lamination and has a thickness of 300/200 nm. Preferably, a thermal evaporation gas utilized in the thermal evaporation process is oxygen, and a thermal evaporation time is 120 minutes, at a temperature of 250° C. Preferably, a thermal evaporation gas utilized in the thermal evaporation process is nitrogen, a thermal evaporation time is 100 minutes, at a temperature of 300° C.

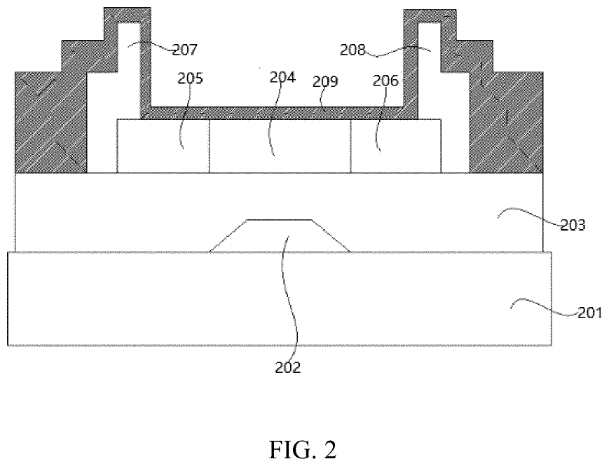

In accordance with the manufacturing method as described above, a back channel etching type TFT array substrate is capable of being manufactured, as shown in FIG. 2.

The TFT array substrate comprise a substrate 201; a gate electrode 202 formed on a surface of the substrate 201; a gate insulating layer 203 formed on the surface of the substrate 201; an active layer formed on a surface of the gate insulting layer 203, the active layer comprising a channel 204, a source doped region 205 located at an end of the channel, and a drain doped region 206 located at another end of the channel; a source electrode 207 and a drain electrode 208 both formed on the surface of the substrate 201; and a passivation layer 110 formed on the surface of the substrate.

The source doped region 205 and the drain doped region 206 are made conductive.

It is understood that the invention may be embodied in other forms within the scope of the claims. Thus the present examples and embodiments are to be considered in all respects as illustrative, and not restrictive, of the invention defined by the claims.

What is claimed is:

1. A manufacturing method of a thin film transistor (TFT) array substrate, comprising:
S10, providing a substrate and forming a gate electrode on a surface of the substrate, and forming a gate insulating layer on the surface of the substrate;
S20, forming an active layer on a surface of the gate insulating layer, the active layer comprising a channel, a source doped region located at an end of the channel, and a drain doped region located at another end of the channel;
S30, forming a protective layer on a surface of the channel, and making the source doped region and the drain doped region conductive;
S40, forming a metal layer on the substrate, and etching the metal layer to form a source electrode and a drain electrode; and
S50, stripping the protective layer, and forming a passivation layer on the surface of the substrate.

2. The manufacturing method of a TFT array substrate of claim 1, wherein the active layer is made of metal oxide comprising indium gallium zinc oxide or indium zinc oxide.

3. The manufacturing method of a TFT array substrate of claim 1, wherein the protective layer is a photoresist.

4. The manufacturing method of a TFT array substrate of claim 1, wherein the step S30 further comprises:
S301, forming patterns on the substrate through a halftone mask after developing the substrate; and
S302, performing an ashing process on the protective layer.

5. The manufacturing method of a TFT array substrate of claim 4, wherein a gas utilized in the ashing process is one or a combination of oxygen and trifluoromethane, and an ashing time is between 20 to 100 seconds.

6. The manufacturing method of a TFT array substrate of claim 1, wherein a gas utilized in making the source doped region and the drain doped region conductive is a noble gas, and a time of making the source doped region and the drain doped region conductive is between 30 to 60 seconds.

7. The manufacturing method of a TFT array substrate of claim 1, wherein the source electrode and the drain electrode are made of copper.

8. The manufacturing method of a TFT array substrate of claim 1, wherein the gate insulating layer and the passivation layer are composite layer structures made of a combination of at least two materials of silicon oxide, silicon nitride, or nitrogen-silicon compounds.

9. The manufacturing method of a TFT array substrate of claim 1, wherein the active layer has a thickness of 40 nanometers, both the source electrode and the drain electrode have a thickness of 500 nanometers, and the passivation layer has a thickness of 100 to 400 nanometers.

10. A thin film transistor (TFT) array substrate manufactured by the method of claim 1, comprising:
a substrate;
a gate electrode formed on a surface of the substrate;
a gate insulating layer formed on the surface of the substrate;
an active layer formed on a surface of the gate insulting layer, the active layer comprising a channel, a source doped region located at an end of the channel, and a drain doped region located at another end of the channel;
a source electrode and a drain electrode both formed on the surface of the substrate; and
a passivation layer formed on the surface of the substrate.

11. A thin film transistor (TFT) array substrate manufactured by the method of claim 4, comprising:
a substrate;
a gate electrode formed on a surface of the substrate;
a gate insulating layer formed on the surface of the substrate;
an active layer formed on a surface of the gate insulting layer, the active layer comprising a channel, a source doped region located at an end of the channel, and a drain doped region located at another end of the channel;
a source electrode and a drain electrode both formed on the surface of the substrate; and
a passivation layer formed on the surface of the substrate.
